(19) United States
(12) Patent Application Publication
(10) Pub. No.: US 2026/0060049 A1
(43) Pub. Date: Feb. 26, 2026

(54) METHOD OF FORMING SEMICONDUCTOR STRUCTURE

(71) Applicant: NANYA TECHNOLOGY CORPORATION, New Taipei City (TW)

(72) Inventor: Shao-En YEH, New Taipei City (TW)

(21) Appl. No.: 18/813,036

(22) Filed: Aug. 23, 2024

(51) Int. Cl. H01L 21/3105; H01L 21/02; H01L 21/027; H01L 21/311

(52) U.S. Cl. CPC H01L 21/31053; H01L 21/02565; H01L 21/0276; H01L 21/31105

(57) ABSTRACT

A method of forming a semiconductor structure includes forming a photoresist pattern on an anti-reflective layer on a wafer; forming an oxide layer on the anti-reflective layer and the photoresist pattern, wherein the oxide layer has a protruding portion overlapping the photoresist pattern; forming a polish stop layer along a top surface of the oxide layer; forming a buffer layer on the polish stop layer; polishing the buffer layer such that at least a portion of the buffer layer is removed and the polish stop layer is exposed; and etching the buffer layer, the polish stop layer and the oxide layer such that the photoresist pattern is exposed.

### BACKGROUND

### Field of Invention

The present disclosure relates to a method of forming a semiconductor structure.

### Description of Related Art

Transferring a LF pattern to a semiconductor structure usually includes forming photoresist pattern and various oxide layers on the wafer. Thereafter, the oxide layers are polished and etched for the following process to transfer the pattern. One of the oxide layers may serve as a buffer layer to protect the underlying structure from damage and erosion caused by the polish and/or etch process.

Nevertheless, conventional processes of polishing oxide layers cannot provide sufficiently uniform surface, resulting in that adjustments to the following etch process are generally required. The thicknesses of different wafers are unstable and the uniformity of the thickness of one wafer is bad, which cause etch step need to manually adjust etch process time.

### SUMMARY

According to one embodiment of the present disclosure, a method of forming a semiconductor structure includes forming a photoresist pattern on an anti-reflective layer on a wafer; forming an oxide layer on the anti-reflective layer and the photoresist pattern, wherein the oxide layer has a protruding portion overlapping the photoresist pattern; forming a polish stop layer along a top surface of the oxide layer; forming a buffer layer on the polish stop layer; polishing the buffer layer such that at least a portion of the buffer layer is removed and the polish stop layer is exposed; and etching the buffer layer, the polish stop layer and the oxide layer such that the photoresist pattern is exposed.

In some embodiments, polishing the buffer layer is performed such that the polish stop layer on the protruding portion of the oxide layer is exposed.

In some embodiments, polishing the buffer layer is performed to further remove a top portion of the buffer layer not overlapping the photoresist pattern.

In some embodiments, polishing the buffer layer is performed such that a top surface the buffer layer not overlapping the photoresist pattern is coplanar with a top surface of the polish stop layer on the protruding portion of the oxide layer.

In some embodiments, polishing the buffer layer is performed such that the top surface of the oxide layer overlapping the photoresist pattern is recessed and exposed through the polish stop layer.

In some embodiments, the buffer layer has a thickness in the range from 50 nanometers to 60 nanometers after polishing the buffer layer.

In some embodiments, polishing the buffer layer includes dispensing a slurry and a surfactant.

In some embodiments, a friction of the polish stop layer against the slurry and a friction of the buffer layer against the slurry are different.

In some embodiments, a material of the polish stop layer includes silicon nitrite, and a material of the buffer layer comprises TEOS oxide.

In some embodiments, the slurry is dispensed at a rate in a range from 50 milliliters to 60 milliliters per minute.

In some embodiments, the surfactant is dispensed at a rate in a range from 200 milliliters to 350 milliters per minute.

In some embodiments, the method of forming the semiconductor structure further includes forming a nitrite layer on the wafer; and forming the anti-reflective layer on the nitrite layer before forming the photoresist pattern.

In some embodiments, the anti-reflective layer is a dielectric coating film, and a material of the anti-reflective layer comprises carbon.

In some embodiments, the buffer layer has a thickness in a range from 150 nanometers to 250 nanometers.

According to another embodiment of the present disclosure, a method of forming a semiconductor structure includes forming a nitrite layer on a wafer; forming an anti-reflective layer on the nitrite layer; forming a photoresist pattern on the anti-reflective layer; forming an oxide layer on the anti-reflective layer and the photoresist pattern, wherein the oxide layer has a protruding portion overlapping the photoresist pattern; forming a polish stop layer along a top surface of the oxide layer; forming a buffer layer on the polish stop layer; and polishing the buffer layer such that at least a portion of the buffer layer is removed and the polish stop layer is exposed.

In some embodiments, polishing the buffer layer is performed such that the polish stop layer on the protruding portion of the oxide layer is exposed.

In some embodiments, polishing the buffer layer is performed to further remove a top portion of the buffer layer above a top surface of the polish stop layer on the protruding portion of the oxide layer.

In some embodiments, polishing the buffer layer is performed such that a top surface the buffer layer not overlapping the photoresist pattern is coplanar with a top surface of the polish stop layer on the protruding portion of the oxide layer.

In some embodiments, polishing the buffer layer comprises dispensing a slurry and a surfactant.

In some embodiments, a friction of a material of the polish stop layer against the slurry and a friction of a material of the oxide layer against the slurry are different.

In the method of forming the semiconductor structure as described above, by using the polish stop layer, the performance of the polish process is improved, a better uniformity of the semiconductor structure is obtained, and hence the manually adjustments (e.g. etch process time adjustment) to the etch process are generally not required.

It is to be understood that both the foregoing general description and the following detailed description are by examples, and are intended to provide further explanation of the invention as claimed.

### BRIEF DESCRIPTION OF THE DRAWINGS

The disclosure can be more fully understood by reading the following detailed description of the embodiment, with reference made to the accompanying drawings as follows:

FIG. 1 is a flow chart of a method of forming a semiconductor structure according to one embodiment of the present disclosure.

FIGS. 2 to 7 are cross-sectional views of various stages of a method of forming a semiconductor structure according to some embodiments of the present disclosure.

FIGS. 8 and 9 are cross-sectional views of various stages of a method of forming a semiconductor structure according to another embodiment of the present disclosure.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

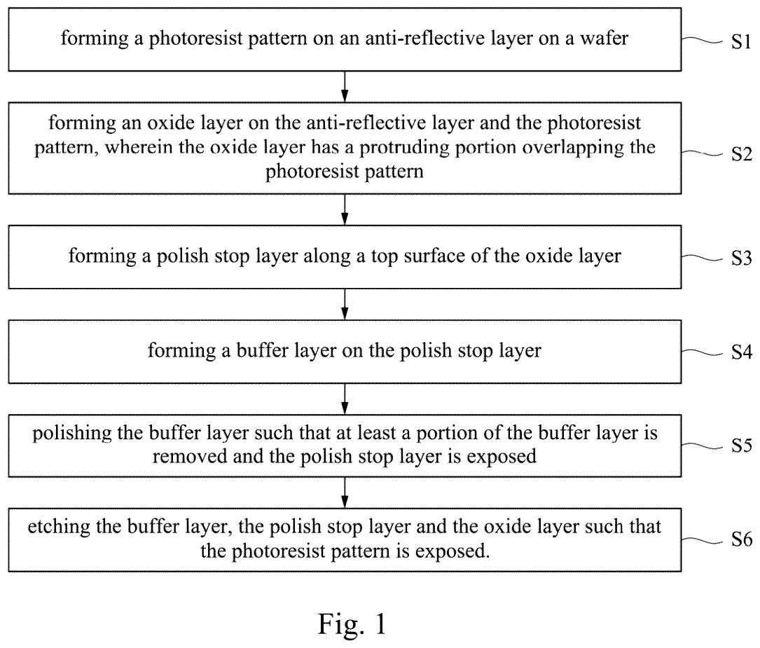

FIG. 1 is a flow chart of a method of forming a semiconductor structure according to one embodiment of the present disclosure. Referring to FIG. 1, in step S1, a photoresist pattern is formed on an anti-reflective layer on a wafer. Next, in step S2, an oxide is formed layer on the anti-reflective layer and the photoresist pattern, wherein the oxide layer has a protruding portion overlapping the photoresist pattern. Subsequently, in step S3, a polish stop layer is formed along a top surface of the oxide layer. Then, in step S4, a buffer layer is formed on the polish stop layer. Afterwards, in step S5, the buffer layer is polished such that at least a portion of the buffer layer is removed and the polish stop layer is exposed. Thereafter, in step S6, the buffer layer, the polish stop layer and the oxide layer is etched such that the photoresist pattern is exposed.

Each of aforementioned steps S1 to S6 may include plural detailed steps. The method of forming the semiconductor structure may further include other steps between step S1 and step S6, and may include other steps before step S1 and after step S6. In the following description, step S1 to step S6 described above will be explained in detail.

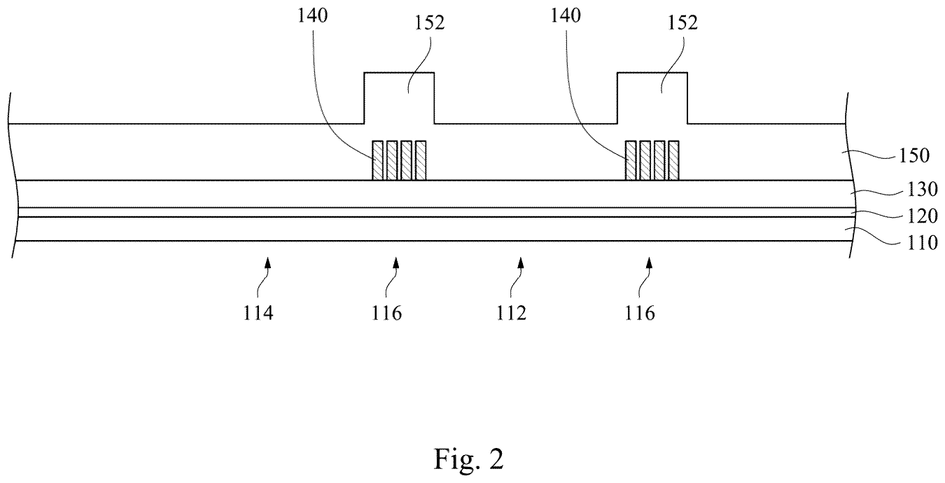

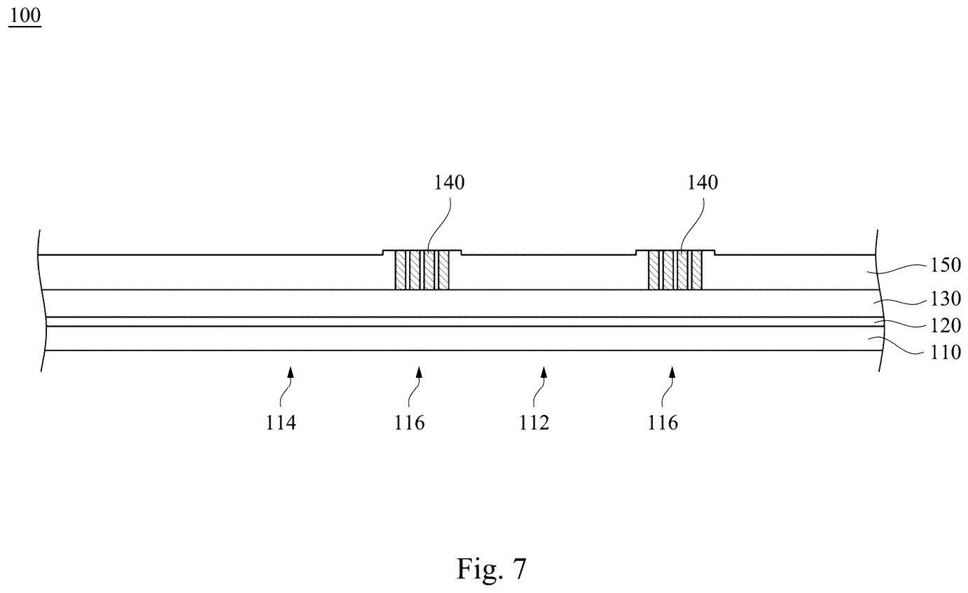

FIGS. 2 to 7 are cross-sectional views of various stages of a method of forming a semiconductor structure 100 (see FIG. 7) according to some embodiments of the present disclosure. Referring to FIG. 2, a photoresist pattern 140 is formed on an anti-reflective layer 130 on a wafer 110. In the present embodiment, the wafer 110 includes an array region 112, a peripheral region 114, and a device region 116, in which the device region 116 may include a sense amplifier (SA) circuit and/or a sub-word line driver (SWD) circuit, and the photoresist pattern 140 overlaps the device region 116.

The photoresist pattern 140 is used to transfer a pattern or a layout, such as an LF pattern, to the semiconductor structure 100. Although the photoresist pattern 140 is illustrated as having two parts overlapping two device regions 116 of the wafer 110 in FIG. 2, the number, the configuration and the appearance of the photoresist layer 140 are not limited by this.

In the present embodiment, before the photoresist pattern 140 is formed, a nitrite layer 120 is formed on the wafer 110, and the anti-reflective layer 130 is formed on the nitrite layer. The nitrite layer 120 and the anti-reflective layer 130 allow the photoresist pattern 140 to be more precisely formed by absorbing the standing wave during the development of photoresist pattern 140. In some embodiments, the anti-reflective layer 130 is a dielectric anti-reflective coating (DARC) film, and the material of the anti-reflective layer 130 includes carbon.

After the photoresist pattern 140 is formed, an oxide layer 150 is formed on the photoresist pattern 140 and the anti-reflective layer 130. The oxide layer 150 has a protruding portion 152 overlapping the photoresist pattern 140. In the present embodiment, the oxide layer 150 is formed using an atomic layer deposition (ALD) process. The material of the oxide layer 150 includes silicon oxide.

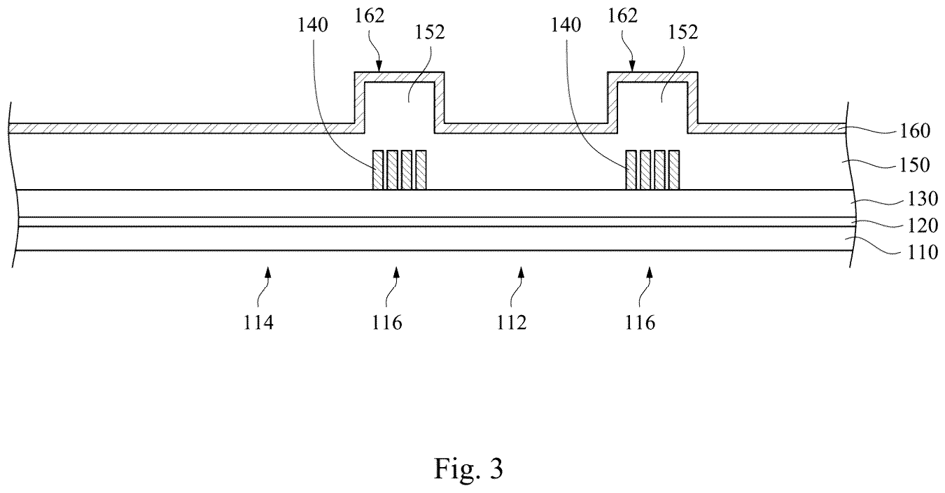

Thereafter, referring to FIG. 3, a polish stop layer 160 is formed along a top surface of the oxide layer 150. In the present embodiment, the polish stop layer 160 is formed using an atomic layer deposition (ALD) process. The material of the polish stop layer 160 includes silicon nitrite.

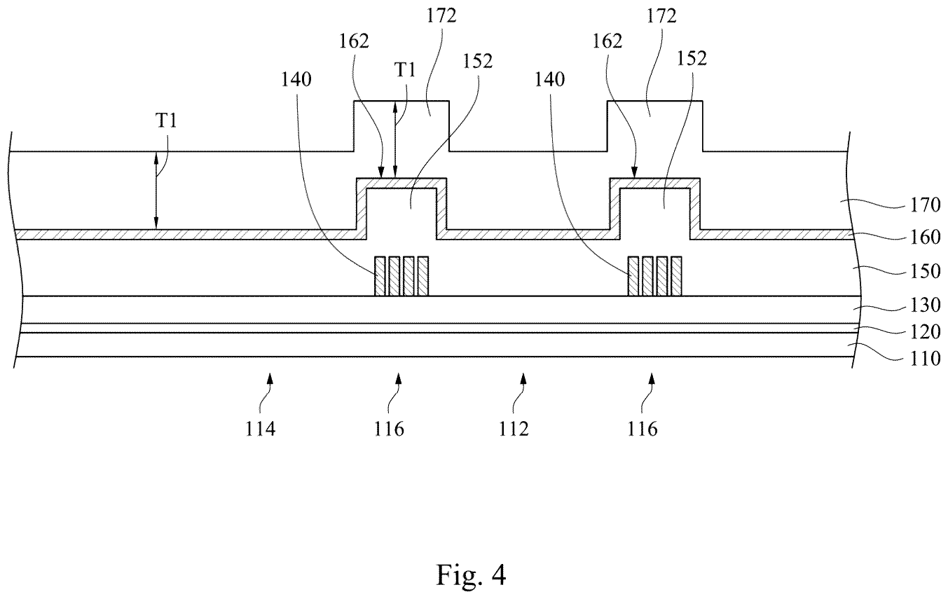

After the polish stop layer 160 is formed, referring to FIG. 4, a buffer layer 170 is formed on the polish stop layer 160. The buffer layer 170 has a top portion 172 above a top surface 162 of the polish stop layer 160 on the protruding portion 152. In the present embodiment, the buffer layer 170 is formed by depositing tetraethoxysilane (TEOS) oxide. In other words, the material of buffer layer 170 includes TEOS oxide. The buffer layer 170 has a thickness T1 in a range from 150 nanometers to 250 nanometers, e.g. 200 nanometers.

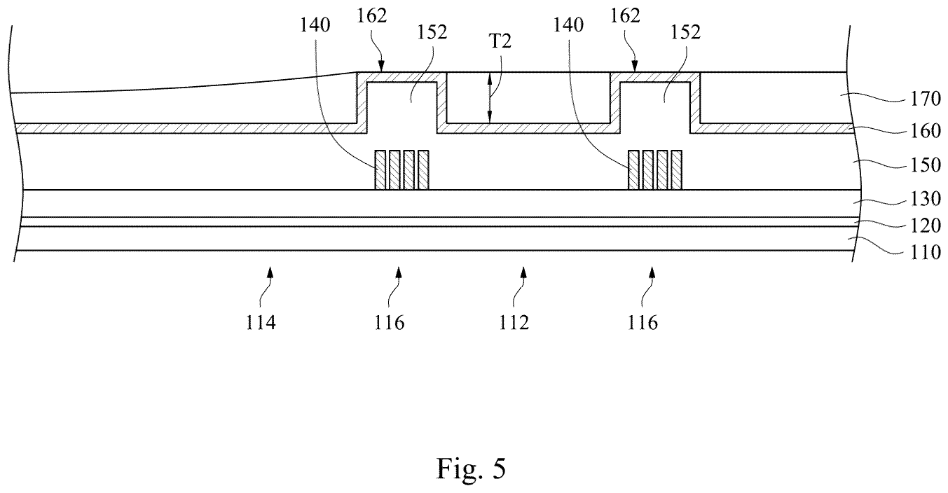

Thereafter, referring to FIG. 5, the buffer layer 170 is polished such that at least a portion (e.g. the top portion 172 of FIG. 4) of the buffer layer 170 is removed and the polish stop layer 160 is exposed. In this embodiment, another top portion of the buffer layer 170 not overlapping the photoresist pattern 140 is removed. The buffer layer 170 is polished using a chemical mechanical planarization (CMP) process. In the present embodiment, polishing the buffer layer 170 is performed such that the polish stop layer 160 on the protruding portion 152 of the oxide layer 150 is exposed. That is, the top portion 172 of the buffer layer 170 is removed. The thickness T2 of the buffer layer 170 overlapping the array region 112 of wafer 110 may be in a range from 45 nanometers to 65 nanometers, e.g., 50 nanometers, after polishing the buffer layer 170.

Polishing the buffer layer 170 includes dispensing a slurry and a surfactant. In some embodiments, polishing the buffer layer 170 includes a CMP process that uses the slurry and the surfactant. In the present embodiment, the slurry is dispensed at a rate in a range from 50 milliliters to 60 milliliters per minute, e.g., 55 milliliters per minute. The surfactant is dispensed at a rate in a range from 200 milliliters to 350 milliliters per minute, e.g., 220 milliliters per minute. The down-force applied in the CMP process of polishing the buffer layer 170 is reduced.

Polishing the buffer layer 170 includes an end-point detection (EPD) process that detects the torque change of the motor of a polishing device. In the present disclosure, because of the difference between the material of the polish stop layer 160 (i.e., silicon nitrite) and the material of the buffer layer 170 (i.e., TEOS oxide), a friction of the polish stop layer 160 against the slurry and a friction of the buffer layer 170 against the slurry are different. Consequently, by applying the EPD process and detecting the torque change of the motor of the polishing device due to the polish stop layer 160 on the protruding portion 152 of the oxide layer 150, the polish process can be stopped exactly when the first change of torque is detected and the polish stop layer 160 on the protruding portion 152 of the oxide layer 150 is exposed.

In the present embodiment, the use of the polish stop layer 160, the use of the surfactant and the use of the EPD process reduce the step height of the surface of the oxide layer 150 and improve the preciseness of polishing the buffer layer 170. Therefore, the within-wafer (WiW) uniformity of the semiconductor structure 100 can be controlled and improved by applying the method described previously.

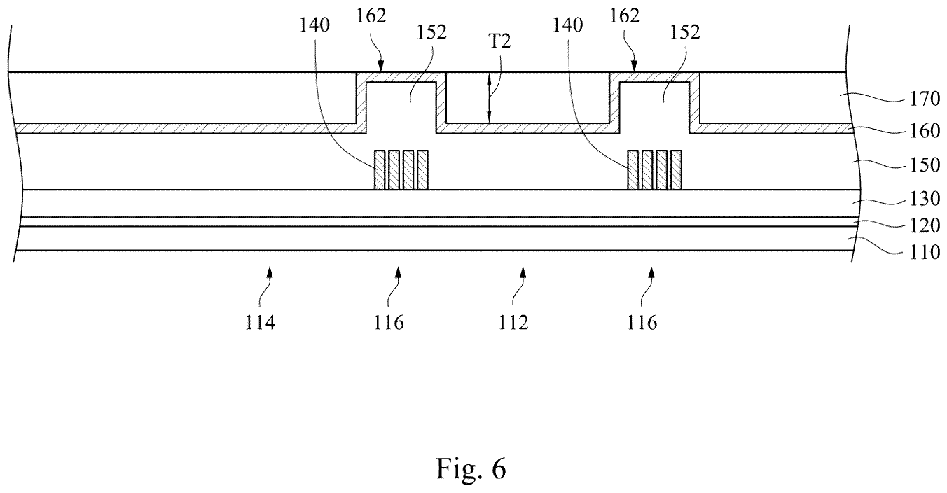

Referring to FIG. 6, in another embodiment, polishing the buffer layer 170 includes dispensing surfactant at a rate in a range from 300 milliliters to 350 milliliters per minute, e.g., 330 milliliters per minute, and the down-force applied is not reduced. By increasing the flow rate of the surfactant, the erosion of the buffer layer 170 on the peripheral region 114 of the wafer 110 is reduced, and the top surface of the buffer layer 170 not overlapping the photoresist pattern 140 (e.g., the buffer layer 170 on the peripheral region 114 of the wafer 110) is coplanar with the top surface 162 of the polish stop layer 160 on the protruding portion 152 of the oxide layer 150. Thus, the wafer-to-wafer (WtW) uniformity of the semiconductor structure 100 is also improved by the method of the present embodiment.

Thereafter, referring to FIG. 7, the buffer layer 170, the polish stop layer 160 and the oxide layer 150 are etched such that the photoresist pattern 140 is exposed. After etching the buffer layer 170, the polish stop layer 160 and the oxide layer 150, a top surface of the oxide layer 150 and the photoresist pattern 140 allow further processes to transfer a pattern to the semiconductor structure 100. Because the polish process to the buffer layer 170, as described previously, is precise and well-controlled, the etch process to the buffer layer 170, the polish stop layer 160 and the oxide layer 150 may not require adjustments to the process time and/or other parameters. For, example, the etch step does not need to manually adjust the etch process time.

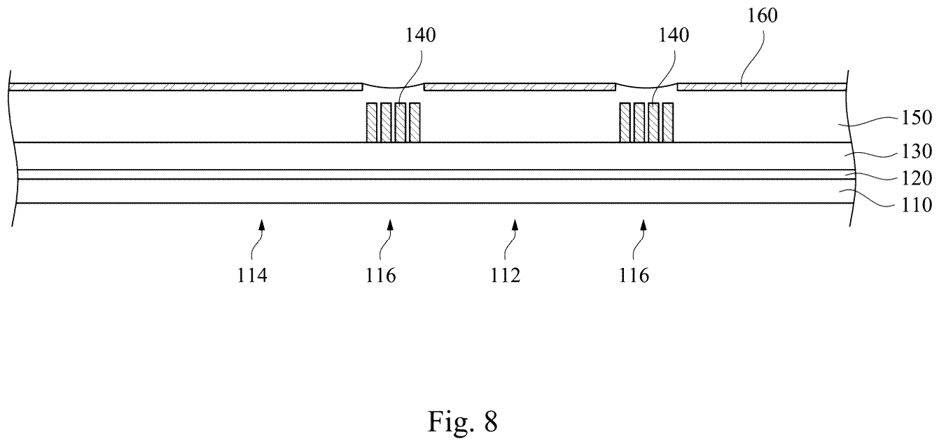

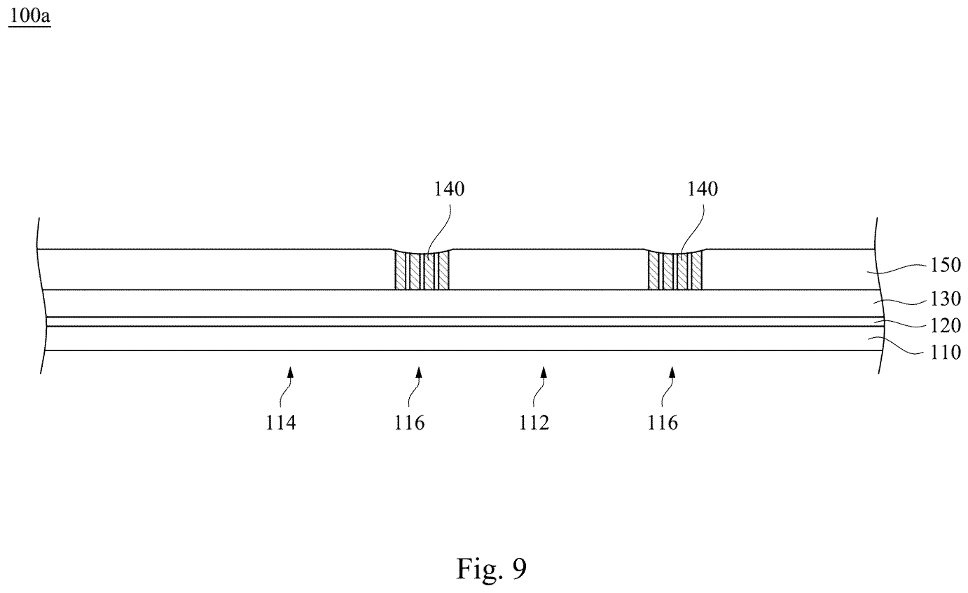

FIGS. 8 and 9 are cross-sectional views of various stages of a method of forming a semiconductor structure 100a according to another embodiment of the present disclosure. Referring to FIGS. 4 and 8, after the structure of FIG. 4 is formed, polishing the buffer layer 170 is performed such that the top surface of the oxide layer 150 overlapping the photoresist pattern 140 is recessed and exposed through the polish stop layer 160. That is, the protruding portion 152 of the oxide layer 150 is removed after the buffer layer 170 is polished. In the present embodiment, polishing the buffer layer 170 removes the entire buffer layer 170 and exposes the polish stop layer 160 not on the protruding portion 152 of the oxide layer 150.

In the present embodiment, EPD process is also applied to detect the torque change of the motor of the polishing device due to the polish stop layer 160 not on the protruding portion 152 of the oxide layer 150. In particular, when the polish stop layer 160 not on the protruding portion 152 of the oxide layer 150 is exposed, a second change of the torque can be detected.

Thereafter, referring to FIG. 9, the polish stop layer 160 and the oxide layer 150 are etched such that the photoresist pattern 140 is exposed. As a result, a semiconductor structure 100a is formed. Because the polish process to the buffer layer 170, as described previously, is precise and well-controlled, the process of etching the polish stop layer 160 and the oxide layer 150 may not require adjustments to the process time and/or other parameters. In the present embodiment, slight erosion to the photoresist pattern 140 may occur, but the erosion does not affect the forming of semiconductor structure 100a. Using the polish process of the present embodiment, the WiW uniformity of the semiconductor structure 100a, the WtW uniformity of the semiconductor structure 100a, the die-to-die (DtD) uniformity of the semiconductor structure 100a and the preciseness of polishing are improved.

In conclusion, in the method of forming the semiconductor structure as described above, by using the polish stop layer, the performance of the polish process is improved, a better uniformity of the semiconductor structure is obtained, and hence the adjustments (e.g. process time adjustment) to the etch process are generally not required.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A method of forming a semiconductor structure, comprising:
forming a photoresist pattern on an anti-reflective layer on a wafer;
forming an oxide layer on the anti-reflective layer and the photoresist pattern, wherein the oxide layer has a protruding portion overlapping the photoresist pattern;
forming a polish stop layer along a top surface of the oxide layer;
forming a buffer layer on the polish stop layer;
polishing the buffer layer such that at least a portion of the buffer layer is removed and the polish stop layer is exposed; and
etching the buffer layer, the polish stop layer and the oxide layer such that the photoresist pattern is exposed.

2. The method of claim 1, wherein polishing the buffer layer is performed such that the polish stop layer on the protruding portion of the oxide layer is exposed.

3. The method of claim 2, wherein polishing the buffer layer is performed to further remove a top portion of the buffer layer not overlapping the photoresist pattern.

4. The method of claim 2, wherein polishing the buffer layer is performed such that a top surface the buffer layer not overlapping the photoresist pattern is coplanar with a top surface of the polish stop layer on the protruding portion of the oxide layer.

5. The method of claim 1, wherein polishing the buffer layer is performed such that the top surface of the oxide layer overlapping the photoresist pattern is recessed and exposed through the polish stop layer.

6. The method of claim 1, wherein the buffer layer has a thickness in a range from 50 nanometers to 60 nanometers after polishing the buffer layer.

7. The method of claim 1, wherein polishing the buffer layer comprises dispensing a slurry and a surfactant.

8. The method of claim 7, wherein a friction of the polish stop layer against the slurry and a friction of the buffer layer against the slurry are different.

9. The method of claim 1, wherein a material of the polish stop layer comprises silicon nitrite, and a material of the buffer layer comprises TEOS oxide.

10. The method of claim 7, wherein the slurry is dispensed at a rate in a range from 50 milliliters to 60 milliliters per minute.

11. The method of claim 7, wherein the surfactant is dispensed at a rate in a range from 200 milliliters to 350 milliters per minute.

12. The method of claim 1, further comprising:
forming a nitrite layer on the wafer; and
forming the anti-reflective layer on the nitrite layer before forming the photoresist pattern.

13. The method of claim 1, wherein the anti-reflective layer is a dielectric coating film, and a material of the anti-reflective layer comprises carbon.

14. The method of claim 1, wherein the buffer layer has a thickness in a range from 150 nanometers to 250 nanometers.

15. A method of forming a semiconductor structure, comprising:
forming a nitrite layer on a wafer;
forming an anti-reflective layer on the nitrite layer;
forming a photoresist pattern on the anti-reflective layer;
forming an oxide layer on the anti-reflective layer and the photoresist pattern, wherein the oxide layer has a protruding portion overlapping the photoresist pattern;
forming a polish stop layer along a top surface of the oxide layer;
forming a buffer layer on the polish stop layer; and
polishing the buffer layer such that at least a portion of the buffer layer is removed and the polish stop layer is exposed.

16. The method of claim 15, wherein polishing the buffer layer is performed such that the polish stop layer on the protruding portion of the oxide layer is exposed.

17. The method of claim 16, wherein polishing the buffer layer is performed to further remove a top portion of the buffer layer above a top surface of the polish stop layer on the protruding portion of the oxide layer.

18. The method of claim 16, wherein polishing the buffer layer is performed such that a top surface the buffer layer not overlapping the photoresist pattern is coplanar with a top surface of the polish stop layer.

19. The method of claim 15, wherein polishing the buffer layer comprises dispensing a slurry and a surfactant.

20. The method of claim 19, wherein a friction of a material of the polish stop layer against the slurry and a friction of a material of the oxide layer against the slurry are different.
